(19) United States
(12) Patent Application Publication
(10) Pub. No.: US 2015/0162327 A1
(43) Pub. Date: Jun. 11, 2015

(54) SEMICONDUCTOR MODULE

(71) Applicant: ROHM CO., LTD., Kyoto-shi (JP)

(72) Inventor: Masashi NIIYAMA, Kyoto-shi (JP)

(21) Appl. No.: 14/559,431

(22) Filed: Dec. 3, 2014

(30) Foreign Application Priority Data
Dec. 5, 2013 (JP) 2013-252087
Dec. 2, 2014 (JP) 2014-243898

(51) Int. Cl. H01L 27/08; H01L 23/525; H01L 27/06; H01L 23/28

(52) U.S. Cl. CPC H01L 27/0802; H01L 23/28; H01L 23/5256; H01L 27/0805; H01L 27/0682

(57) ABSTRACT

A semiconductor module is provided with a plurality of chip-type passive components, a conductive supporting member onto which the plurality of chip-type passive components are mounted, and a resin sealing part covering the plurality of chip-type passive components and at least a portion of the conductive supporting member. The plurality of chip-type passive components each include a semiconductor substrate, a plurality of electrodes formed on the semiconductor substrate, and a passive circuit connected between the plurality of electrodes.

### BACKGROUND OF THE INVENTION

1. Field of the Invention

The present invention relates to a semiconductor module.

2. Description of Related Art

Heretofore, electrical control circuits in which an integrated circuit module such as an LSI and a plurality of chip-type passive components are mounted onto a wiring board have been widely proposed (e.g., see JP-A-2011-18853). Generally, the number of the chip-type passive components that are required increases as the functionality of the integrated circuit module increases. It is thus sought to make each chip-type passive component very small in size. However, mounting very small chip-type passive components onto a wiring board together with an integrated circuit module is extremely difficult.

### SUMMARY OF THE INVENTION

The present invention was conceived under the above circumstances. In view thereof, an object of the present invention is to provide a semiconductor module that enables very small chip-type passive components to be appropriately integrated into an electrical circuit.

A semiconductor module that is provided by the present invention includes: a plurality of chip-type passive components each equipped with a semiconductor substrate, a plurality of electrodes formed on the semiconductor substrate, and a passive circuit formed on the semiconductor substrate and connected between the plurality of electrodes; a conductive supporting member onto which the plurality of chip-type passive components are mounted; and a resin sealing part covering the plurality of chip-type passive components and at least a portion of the conductive supporting member.

Preferably, the semiconductor substrate of the chip-type passive components directly contacts the resin sealing part.

Preferably, the passive circuit includes a resistive network.

Preferably, the resistive network includes a plurality of resistive elements arrayed on the substrate in a matrix and having equal resistance, a plurality of types of resistor unit bodies configured by electrically connecting to one or more of the resistive elements, a network connection means connecting the plurality of types of resistor unit bodies, and a plurality of fuse films provided in one-to-one correspondence with the resistor unit bodies, and blowable in order to electrically integrate the respective resistor unit bodies into the resistive network or to electrically isolate the respective resistor unit bodies from the resistive network.

Preferably, the resistive elements include a resistor film line that extends on the substrate, and a conductor film laminated on the resistor film line with a fixed interval provided in a line direction, and a portion of the resistor film line that is located in the fixed interval portion where the conductor film is not laminated constitutes one resistive element.

Preferably, a conductor film of the resistive elements, a connecting conductor film included in the resistor unit bodies, a connecting conductor film included in the network connection means, and the fuse films include a metal film of the same material formed in the same layer.

Preferably, in a circuit formation surface of the substrate, a trench dug to a predetermined depth from the circuit formation surface is formed, and the resistive network includes a resistor circuit having a resistive film provided along an inner wall surface of the trench so as to traverse the trench.

Preferably, the resistive network includes a plurality of resistor circuits, and a fuse film blowable in order to electrically integrate an arbitrary resistor circuit into the resistive network or to electrically isolate an arbitrary resistor circuit from the resistive network.

Preferably, the resistive film has a fixed width, and includes a line-like resistor film line that extends linearly. Preferably, the resistive film is formed to extend from an inner surface of the trench to the circuit formation surface outside the trench, and the semiconductor module further includes a wiring film formed in contact with a portion of the resistive film that is formed on the circuit formation surface.

Preferably, the trench extends in a predetermined direction, when the circuit formation surface is seen in plan view, and the resistive film includes a plurality of parallelly arrayed resistor film lines provided along the inner wall surface of the trench so as to traverse the trench, and extending orthogonally to the direction in which the trench extends.

Preferably, the passive circuit includes a plurality of capacitor elements.

Preferably, the passive circuit includes a plurality of fuse films blowable in order to electrically integrate the plurality of capacitor elements between the plurality of electrodes or to electrically isolate the plurality of capacitor elements from between the plurality of electrodes.

Preferably, the passive circuit includes a lower electrode film, a capacitive film, and an upper electrode film that are laminated on the substrate, and one of the lower electrode film and the upper electrode film is divided into a plurality of electrode film portions.

Preferably, the substrate has a circuit formation surface, a back surface on an opposite side to the circuit formation surface, and a side surface connecting the circuit formation surface and the back surface, the passive circuit and the plurality of electrodes are formed on the circuit formation surface, the semiconductor module further includes a resin film covering the circuit formation surface in a state where the plurality of electrodes are exposed, and an intersection part where the back surface and the side surface of the substrate intersect has a rounded shape.

Preferably, a radius of curvature of the rounded shape is 20 μm or less.

Preferably, an intersection part where the circuit formation surface and the side surface of the substrate intersect has a different shape from the rounded shape.

Preferably, the resin film covers the intersection part where the circuit formation surface and the side surface of the substrate intersect.

Preferably, the resin film bulges outwardly of the substrate at the intersection part where the circuit formation surface and the side surface of the substrate intersect.

Preferably, the resin film is provided on an area of the side surface of the substrate that is separated from the back surface toward the circuit formation surface side.

Preferably, the semiconductor module further includes an integrated circuit device mounted onto the conductive supporting member and in electrical contact with the plurality of passive components.

Preferably, the integrated circuit device is in electrical contact with the conductive supporting member via a plurality of wires.

Preferably, the integrated circuit device directly contacts the resin sealing part.

Preferably, the semiconductor module further includes a case interposed between the integrated circuit device and the resin sealing part.

Preferably, the integrated circuit device is mounted directly onto the conductive supporting member.

Preferably, the plurality of passive components include passive components mounted directly onto the integrated circuit device.

Preferably, the conductive supporting member is a wiring board including a base material made of an insulating material and a wiring pattern formed on the base material.

Preferably, the conductive supporting member includes a plurality of leads each made of a metal.

Preferably, the chip-type passive components are mounted directly onto the conductive supporting member.

Preferably, the plurality of passive components include passive components arranged adjacent to each other having dimensions in an adjacent direction of 0.05 to 0.3 mm and a gap therebetween of 50 to 150 μm.

According to configurations such as described above, the chip-type passive components are formed by a semiconductor substrate made of a semiconductor, thus enabling the chip-type passive components to be made remarkably small in size. Also, a semiconductor such as Si has high rigidity. Thus, even if the resin sealing part expands and contracts with use of the semiconductor module in a state where the chip-type passive components are covered by the resin sealing part, there is little possibility of the chip-type passive components being unduly deformed or damaged. Accordingly, chip-type passive components of remarkably small size can be appropriately integrated into an electrical circuit or the like.

Further features and advantages of the present invention will become apparent from the following detailed description with reference to the accompanying drawings.

### BRIEF DESCRIPTION OF THE DRAWINGS

FIG. 1 is a perspective view showing a semiconductor module that is based on a first embodiment of the present invention.

FIG. 2 is a cross-sectional view along a line II-II of FIG. 1.

FIG. 3 is an enlarged cross-sectional view showing a portion of the semiconductor module of FIG. 1.

FIG. 4 is a perspective view showing an example of a chip-type passive component that is used in the semiconductor module of FIG. 1.

FIG. 5 is a plan view showing the chip-type passive component of FIG. 4.

FIG. 6 is an enlarged plan view showing a portion of the chip-type passive component of FIG. 4.

FIG. 7 is a cross-sectional view along a line VII-VII in FIG. 6.

FIG. 8 is a cross-sectional view along a line VIII-VIII in FIG. 6.

FIG. 9 is a plan view showing an example of a semiconductor wafer for forming a chip-type passive component.

FIG. 10 is an enlarged plan view showing a main portion of another example of a chip-type passive component that is used in the semiconductor module of FIG. 1.

FIG. 11 is a cross-sectional view along a line XI-XI in FIG. 10.

FIG. 12 is a perspective view showing a further example of a chip-type passive component that is used in the semiconductor module of FIG. 1.

FIG. 13 is an enlarged cross-sectional view showing a portion of the semiconductor module in which the chip-type passive component shown in FIG. 11 is used.

FIG. 14 is a plan view showing a further example of a chip-type passive component that is used in the semiconductor module of FIG. 1.

FIG. 15 is a cross-sectional view along a line XV-XV in FIG. 14.

FIG. 16 is a cross-sectional view showing a semiconductor module that is based on a second embodiment of the present invention.

FIG. 17 is a cross-sectional view showing a semiconductor module that is based on a third embodiment of the present invention.

FIG. 18 is a perspective view showing a semiconductor module that is based on a fourth embodiment of the present invention.

FIG. 19 is an enlarged perspective view showing a main portion of a modification of the semiconductor module that is based on the first embodiment of the present invention.

FIG. 20 is a perspective view showing a chip-type passive component that is used in the semiconductor module of FIG. 19.

FIG. 21 is a plan view showing a semiconductor module that is based on a fifth embodiment of invention.

FIG. 22 is a cross-sectional view along a line XXII-XXII in FIG. 21.

FIG. 23 is an enlarged cross-sectional view showing a portion of the semiconductor module of FIG. 21.

### DETAILED DESCRIPTION OF THE PREFERRED EMBODIMENTS

Hereinafter, preferred embodiments of the present invention will be described with reference to the drawings.

FIGS. 1 to 3 show a semiconductor module that is based on a first embodiment of the present invention. A semiconductor module A1 of the present embodiment is provided with a wiring board 1, a plurality of chip-type passive components 2, an integrated circuit device 3, and a resin sealing part 4.

The wiring board 1, which is an example of a conductive supporting member, is for supporting the plurality of chip-type passive components 2 and the integrated circuit device 3 and forming a conduction path that is in electrical contact therewith. In the present embodiment, the wiring board 1 is provided with a base material 11, wiring patterns 12, through holes 13, and mounting electrodes 14.

The base material 11 is a plate-like member made of an insulating material such as a glass epoxy resin or a ceramic, for example. The base material 11 is rectangular in shape, for example. The wiring patterns 12 are formed on the base material 11, and are made of a conductive material such as a plating layer formed by laminating Cu, Ni and Au. The wiring patterns 12 are respectively in electrical contact with the plurality of chip-type passive components 2 and the integrated circuit device 3 as appropriate, and are patterned according to the shape, size, arrangement and the like of the plurality of chip-type passive components 2 and the integrated circuit device 3. The through holes 13 pass through the base material 11, and are in electrical contact with a portion of the wiring patterns 12. The mounting electrodes 14 are formed on the opposite surface of the base material 11 to the surface on which the wiring patterns 12 are formed, and are used in order to mount the semiconductor module A1 onto a circuit board or the like, for example. A plurality of mounting electrodes 14 are formed on the semiconductor module A1. Note that, in the case where the base material 11 is made of ceramic, a conductive film or the like that passes around the sides of the base material and brings the wiring patterns 12 into electrical contact with the mounting electrodes 14 may be formed instead of the through holes 13.

The integrated circuit device 3 consists of an integrated circuit formed on one surface of a semiconductor such as Si serving as a base. The integrated circuit device 3 is joined to the wiring board 1 by an Ag paste or the like, for example. Note that the semiconductor serving as the base of the integrated circuit device 3 is joined directly to the wiring board 1, and the integrated circuit device 3 is mounted onto the wiring board 1 as a bare chip. The integrated circuit device 3 has a plurality of pads 31. In the present embodiment, the plurality of pads 31 are arranged at two rows along two parallel sides of the integrated circuit device 3, although this arrangement is merely an example. The pads 31 are respectively connected to a pad portion of the wiring patterns 12 by a wire 32.

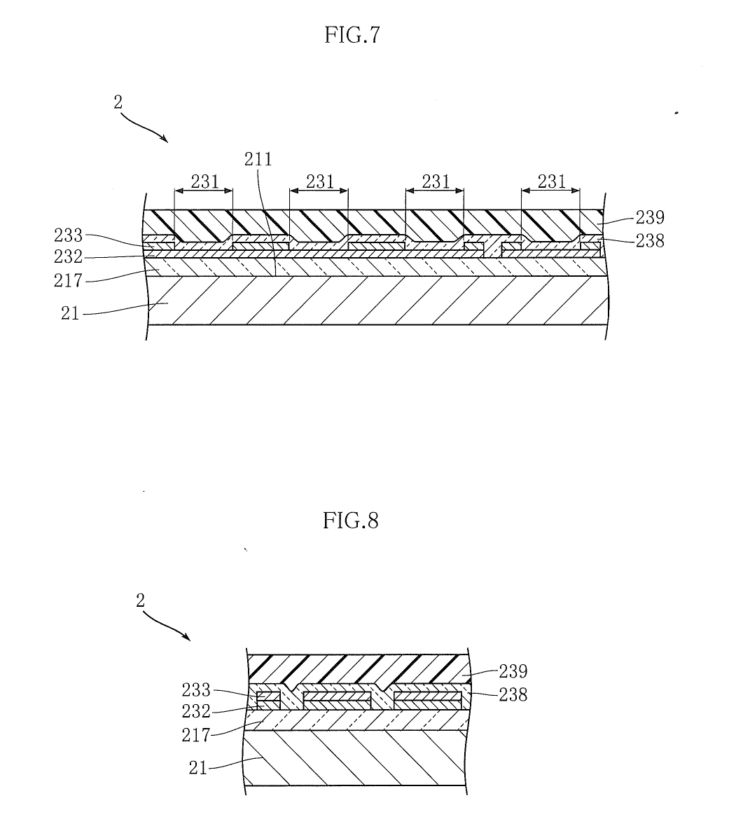

The plurality of chip-type passive components 2 are for achieving a predetermined passive function on the input-output path of the integrated circuit device 3, in order for the integrated circuit device 3 to function properly. Specific configurations of the chip-type passive components 2 include a chip resistor, a capacitor, a diode and a coil. Such chip-type passive components 2 function as components that adjust the time constant in a circuit that includes the integrated circuit device 3. Hereinafter, a chip-type passive component 2 constituted as a chip resistor will be described as an example, with reference to FIGS. 3 to 8.

The chip-type passive component 2 is rectangular parallelepiped, as shown in FIG. 4. To give an example of the size of the chip-type passive component 2, the long sides are about 0.3 mm in length, the short sides are about 0.15 mm in width, and the thickness is about 0.1 mm.

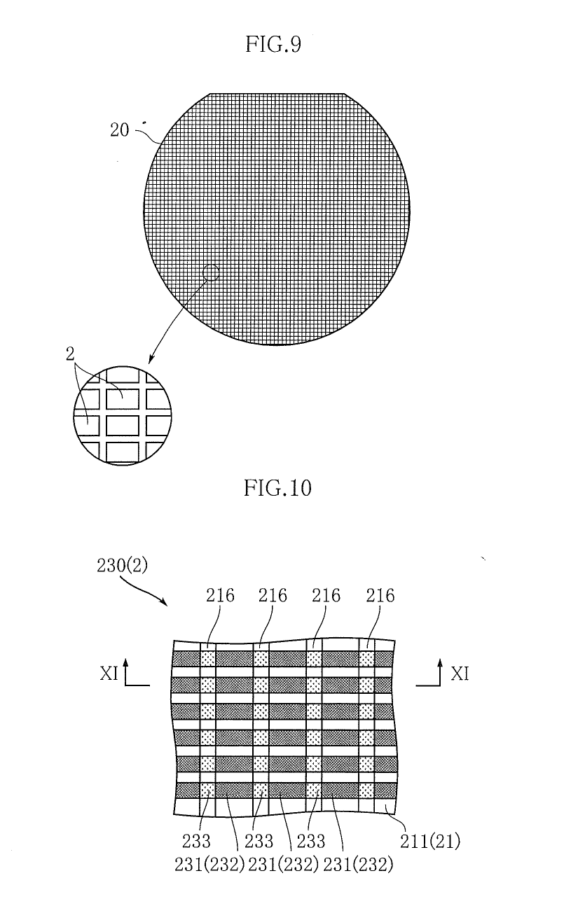

A plurality of chip-type passive components 2 are obtained, as shown in FIG. 9, for example, by forming a large number of chip-type passive components 2 into a grid pattern on a semiconductor wafer 20 made of Si, for example, forming grooves in the semiconductor wafer 20, and then back grinding (or cutting the semiconductor wafer 20). The chip-type passive component 2 is provided with a semiconductor substrate 21, two electrodes 22, and a passive circuit 23.

The semiconductor substrate 21 is approximately rectangular parallelepiped. The semiconductor substrate 21 has a circuit formation surface 211, four side surfaces 212, and a back surface 213. The circuit formation surface 211 is the surface of the semiconductor substrate 21, and is approximately rectangular. The back surface 213 is the opposite surface of the semiconductor substrate 21 to the circuit formation surface 211 in the thickness direction. The circuit formation surface 211 and the back surface 213 are substantially the same shape. The four side surfaces 212 extend orthogonally to the circuit formation surface 211 and the back surface 213, and connect these surfaces.

The circuit formation surface 211 of the semiconductor substrate 21 is entirely covered by an insulating layer 217. The insulating layer 217 is made of SiO₂, for example. Thus, the entire area of the circuit formation surface 211 is, strictly speaking, located on the inner side (back side) of the insulating layer 217, and is not exposed to the outside. Furthermore, the insulating layer 217 on the circuit formation surface 211 is covered with a resin film 239. The resin film 239 made of polyimide, for example.

The two electrodes 22 are arranged close to either short side on the circuit formation surface 211 of the semiconductor substrate 21. Each electrode 22 is made of Au, or is constituted by Au plating the surface of a metal other than Au. As shown in FIG. 3, the two electrodes 22 are joined to the wiring pattern 12 of the wiring board 1 via solder 29, for example.

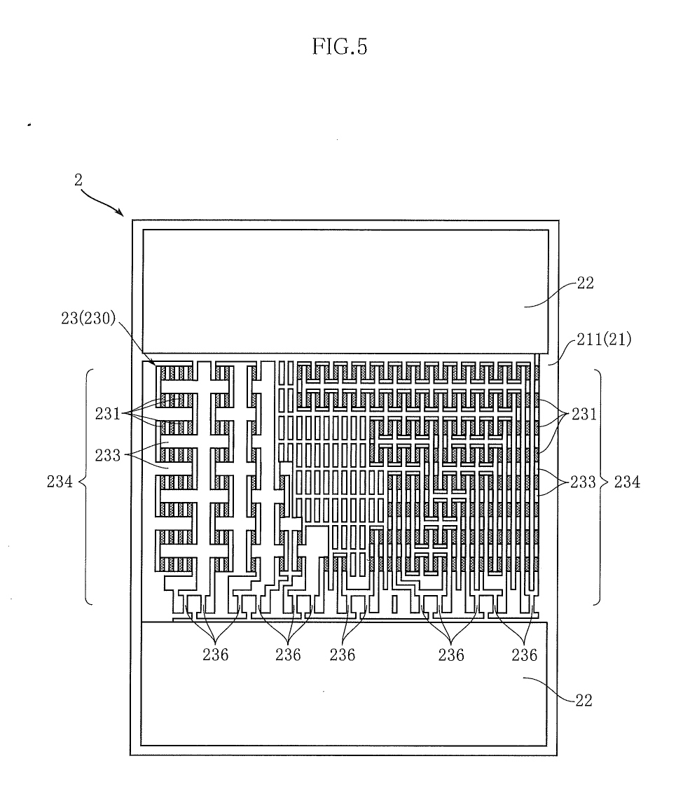

As shown in FIG. 5 the passive circuit 23 is formed between the two electrodes 22, on the circuit formation surface 211 of the semiconductor substrate 21, and is in electrical contact with the two electrodes 22. In the present embodiment, the passive circuit 23 is constituted as a resistive network 230 to which a large number of resistive elements 231 are connected. In the present embodiment, the resistive elements 231 have equal resistance and are arranged in matrix. To give an example of the positional relationship in an arranged state, 44 resistive elements 231 are arranged in the width direction (row direction) of the semiconductor substrate 21, and 352 resistive elements 231 are arranged in total. 1 to 64 of these resistive elements 231 are electrically connected to form a plurality of types of resistor unit bodies 234.

The plurality of types of resistor unit bodies 234 are connected in a predetermined mode by a conductor film 233 serving as network connection means. Furthermore, a plurality of fuse films 236 that are blowable in order to electrically integrate the resistor unit bodies 234 into the resistive network 230 or electrically separate the resistor unit bodies 234 from the resistive network 230 are provided. The plurality of fuse films 236 are arranged along the inner side of one of the electrodes 22 such that the arrangement region is linear. More specifically, the plurality of resistive elements 231 and the conductor film 233 are linearly arranged relative to the fuse films 236.

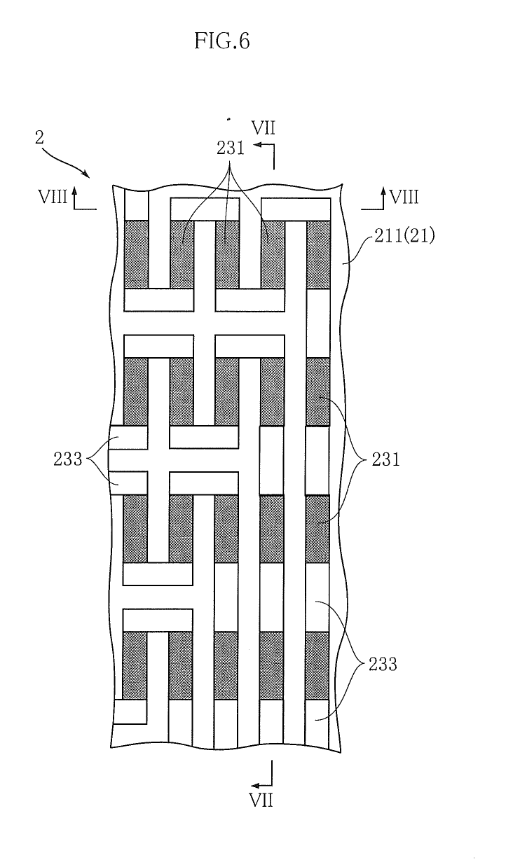

As shown in FIGS. 6 to 8, the insulating layer 217 is formed on the circuit formation surface 211 of the semiconductor substrate 21. A resistor film 232 constituting the resistive elements 231 is arranged on this insulating layer 217. The resistor film 232 is made of TiN or TiON. This resistor film 232 is formed as a plurality of resistive films (hereinafter “resistor film lines”) extending in lines between the two electrodes 22, and the resistor film lines 232 may be cut at predetermined positions in the line direction. An aluminum film serving as the conductor film 233 is laminated on the resistor film lines 232. The conductor film 233 is laminated on the resistor film lines 232 with fixed intervals provided in the line direction.

An electrical feature of such resistor film lines 232 and such a conductor film 233 is that each portion of the resistor film lines 232 that is located in the area of the predetermined interval forms a resistive element 231 having a fixed resistance. In the area where the conductor film 233 is laminated, the resistor film lines 232 are shunted by the conductor film 233. A resistor circuit consisting of the series connection of the resistive elements 231 having equal resistance is thereby formed. Also, adjacent resistor film lines 232 are connected by the conductor film 233 and constitute the resistive network 230.

In the illustrated configuration, the plurality of chip-type passive components 2 are arrayed so as to be oriented with respective long sides parallel to each other. The dimension W of the chip-type passive components 2 in this array direction is 0.05 mm to 0.3 mm. Also, a gap C between the adjacent chip-type passive components 2 in the array direction is 50 μm to 150 μm. That the dimension W and the gap C are such remarkably small values is due to the chip-type passive components 2 being microfabricated in the semiconductor device manufacturing process. For example, the outer shape of the semiconductor substrate 21 is formed by etching. The dimensional accuracy of the chip-type passive components 2 having such a semiconductor substrate 21 is remarkably different from elements that have been chipped by cutting using a rotary blade, for example.

Here, the manufacturing process of the resistive network 230 will be briefly described. First, the circuit formation surface 211 of the semiconductor substrate 21 is thermally oxidized to form a silicon dioxide (SiO₂) layer serving as the insulating layer 217. Next, the resistor film 232 of TiN, TiON or TiSiON is formed over the entire insulating layer 217 by sputtering. Next, the conductor film 233 of aluminum (A1) is laminated on the resistor film 232 by sputtering. Thereafter, using a photolithography process, the conductor film 233 and the resistor film 232 are selectively removed by dry etching, for example, to obtain a configuration in which the resistor film lines 232 and the conductor film 233 having a fixed width are arrayed in the row direction with a fixed interval therebetween in plan view. At this time, areas where the resistor film lines 232 and the conductor film 233 are partially cut are also formed. Subsequently, the conductor film 233 laminated on the resistor film lines 232 is selectively removed. As a result, a configuration in which the conductor film 233 is laminated on the resistor film lines 232 with fixed intervals provided is obtained. Thereafter, a SiN film serving as a protective film 238 is deposited, and a polyimide layer serving as the resin film 239 is laminated on the SiN film.

The fuse films 236 are also formed by the conductor film 233 laminated on the resistor film 232 that forms the resistive elements 231. That is, the fuse films 236 are formed in the same layer as the conductor film 233 laminated on the resistor film 232 that forms the resistive elements 231, using aluminum (A1) which is the same metal material as the conductor film 233. Note that the conductor film 233 is also used to electrically connect the plurality of resistive elements 231, in order to form the resistor unit bodies 234, as mentioned above.

The conductor film 233 and the fuse films 236 are formed, in the same layer laminated on the resistor film 232, by the same manufacturing process (sputtering and photolithography process) using the same metal material (e.g., aluminum). The manufacturing process of this semiconductor module A1 is thereby simplified, and the conductor film 233 and the fuse films 236 can be simultaneously formed utilizing a common mask. Furthermore, alignment with the resistor film 232 is also improved.

In the resistive network 230, arbitrary resistor unit bodies 234 can be electrically integrated into the two electrodes 22, by setting arbitrary fuse films 236 to an open state. In the present embodiment, a configuration is, for example, adopted in which the two electrodes 22 are connected by reference resistor unit bodies 234 whose resistance is 640 ohms assuming that the resistance of one resistive element 231 is 80 ohms. The fuse films 236 are connected in parallel to the reference resistor unit bodies 234, and the plurality of types of resistor unit bodies 234 are respectively shunted by the fuse films 236. In other words, thirteen individual resistor unit bodies 234 of twelve different types are connected in series to the reference resistor unit bodies 234, but because the resistor unit bodies 234 are respectively shunted by the fuse films 236 connected in parallel thereto, electrically, the resistor unit bodies 234 are not integrated into the resistive network 230.

The semiconductor module A1 selectively blows arbitrary fuse films 236 with laser light, for example, according to the required resistance. The resistor unit bodies 234 to which the fuse films 236 that have been blown are connected in parallel will be integrated into the resistive network 230. Therefore, the overall resistance of the resistive network 230 can be set to a resistance obtained by the resistor unit bodies 234 corresponding to the blown fuse films 236 being connected in series and integrated.

Also, the plurality of types of resistor unit bodies 234 are constituted by connecting resistive elements 231 having equal resistance in series, such that the number resistive elements is increased in geometric progression, 1, 2, 4, 8, 16, 32 and 64. Since these resistor unit bodies 234 are connected in series in a state of being shunted by the fuse films 236, the overall resistance of the resistive network 230 can be set to arbitrary resistances over a wide range from low resistances to high resistances by selectively blowing the fuse films 23.

The resin sealing part 4 covers the plurality of chip-type passive components 2, the integrated circuit device 3 and one surface of the wiring board 1, and is made of a black epoxy resin, for example. As shown in FIG. 3, the resin sealing part 4 directly contacts the side surfaces 212, the back surface 213 and the like of the semiconductor substrate 21 of the chip-type passive components 2. The resin sealing part 4 may also be similarly configured to directly contact a base material composed of the semiconductor of the integrated circuit device 3.

Next, the operation of the semiconductor module A1 will be described.

According to the present embodiment, the chip-type passive components 2 are formed by the semiconductor substrate 21 made of a semiconductor, thus enabling the chip-type passive components 2 to be made remarkably small in size. Also, a semiconductor such as Si has high rigidity. Thus, even if the resin sealing part 4 expands and contracts with use of the semiconductor module A1 in a state where the chip-type passive components 2 are covered by the resin sealing part 4, there is little possibility of the chip-type passive components 2 being unduly deformed or damaged. Accordingly, chip-type passive components 2 of remarkably small size can be appropriately integrated into an electrical circuit or the like.

As a result of the resin sealing part 4 being configured to directly contact the semiconductor substrate 21, miniaturization of the overall size and high density packaging can be achieved, compared with the case where, for example, a passive component module that is separately provided with only the chip-type passive components 2 is formed and mounted, by covering the chip-type passive components 2 with a dedicated sealing resin material. Also, as a result of the semiconductor substrate 21 being made of a semiconductor, there is little possibility of the semiconductor substrate 21 being unduly deformed or damaged by stress produced by the resin sealing part 4, even with a configuration in which the semiconductor substrate 21 directly contacts the resin sealing part 4.

Chip-type passive components 2 that are used as auxiliary components of the integrated circuit device 3 are preferably mounted so as to be appropriately oriented in appropriate positions relative to the integrated circuit device 3. When the chip-type passive components 2 are remarkably small in size, extremely advanced techniques are required in the mounting process of mounting these chip-type passive components 2 onto a circuit board or the like. Particularly in the case where the chip-type passive components 2 are shipped from the manufacturer directly after being manufactured, and are mounted by a user company, the user company needs to select and pick up desired chip-type passive components 2 from the plurality of chip-type passive components 2 stuck to tape or the like, for example, and mount the chip-type passive components 2. Alternatively, in the case where the plurality of chip-type passive components 2 are not delivered in an orderly state, the user company will also need to properly orient the chip-type passive components 2. Furthermore, cases may also arise, from the viewpoint of protecting the chip-type passive components 2 during transport or the like, where the chip-type passive components 2 will need to be shipped as a passive component module by being covered with a dedicated sealing resin material. In the present embodiment, as shown in FIG. 9, a plurality of chip-type passive components 2 are orderly arranged in a matrix in the state where the plurality of chip-type passive components 2 were manufactured by dividing the semiconductor wafer 20. If arbitrary chip-type passive components 2 are mounted onto the wiring board 1 in this state, the difficulties involved in mounting the chip-type passive components 2 can be mitigated. Also, since the necessity for protecting the chip-type passive components 2 during transport or the like is comparatively low, covering the chip-type passive components 2 with a dedicated sealing resin material or the like is not enforced.

The resistive network 230 formed on the semiconductor substrate 21 can be manufactured by very fine fabrication, thus enabling formation in an extremely small area, and the setting of precise resistances. Also, by selectively opening the fuse films 236, a plurality of types of resistances can be precisely set by a single chip-type passive component 2. Accordingly, the chip-type passive components 2 can be operated with high accuracy as auxiliary components of the integrated circuit device 3.

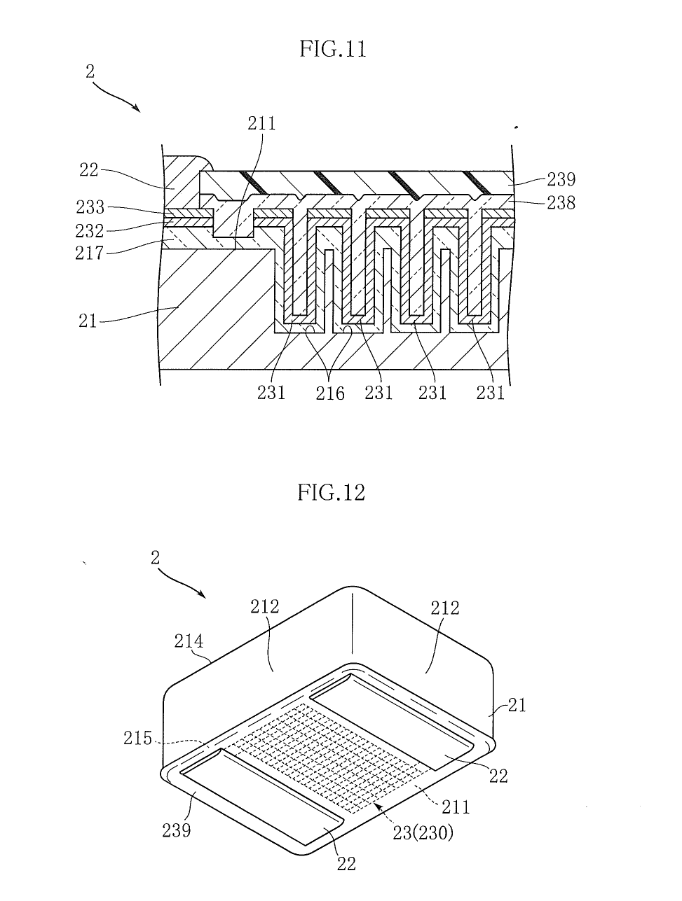

FIGS. 10 to 18 show modifications and other embodiments of the present invention. Note that, in these diagrams, the same reference signs as the above embodiment are given to constituent elements that are the same as or similar to the above embodiment.

FIGS. 10 and 11 show a modification of the chip-type passive components 2 that are used in the semiconductor module A1.

In the present modification, a plurality of trenches 216 are formed in the circuit formation surface 211 of the semiconductor substrate 21. The plurality of trenches 216 are formed in the semiconductor substrate 21 by a technique such as dry etching, for example. As shown in FIG. 10, in the present modification, the plurality of trenches 216 each extends in the vertical direction in the diagram, and are arranged in parallel to each other. The circuit formation surface 211 and the inner wall surface and the bottom surface of the plurality of trenches 216 are covered by an insulating layer 217 made of SiO₂ by being thermally oxidized, for example.

A resistor film 232 is formed on the insulating layer 217 provided on the circuit formation surface 211 and in the trenches 216. The resistor film 232 is made of TiN, TiON, or TiSiON. The resistor film 232 is provided on the insulating layer 217 along the inner wall surface and the bottom surface of the trenches 216 so as to traverse the trenches 216 at right angles thereto. Such a resistor film 232 forms resistor film lines 232.

An aluminum film serving as a conductor film 233 is laminated on portions of the resistor film lines 232 that are arranged on the circuit formation surface 211. In the portions of the resistor film lines 232 on which the conductor film 233 is laminated, the conductor film 233 is shunted by the resistor film 232. Thus, in the chip-type passive components 2 of the present modification, portions of the resistor film lines 232 that extend along the inner wall surface and the bottom surface of the trenches 216 form the resistive elements 231. The resistor film line's 232 forming the resistive elements 231 can be set to a predetermined length by adjusting the depth of the trenches 216. For example, the depth of the trenches 216 can be from tens to hundreds of micrometers. The resistive elements 231 can thus be set to a high resistance. As a result, the chip-type passive components 2, as a whole, serve as chip resistors with respect to which high resistance is achieved. Note that although, in the present modification, the conductor film 233 is provided in order to improve resistance accuracy, a configuration can also be adopted in which the conductor film 233 for partitioning the plurality of resistive elements 231 is not provided in the case where high resistance is prioritized.

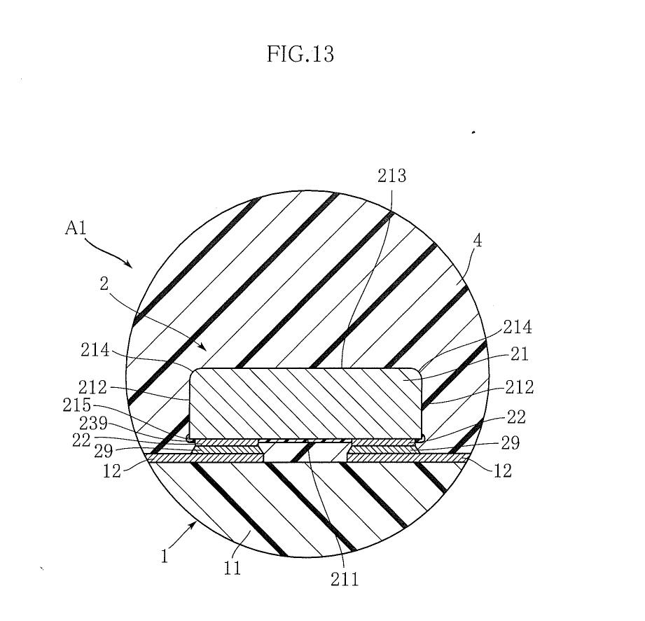

FIGS. 12 and 13 show another modification of the chip-type passive components 2. In the present modification, four intersection parts 214 which are portions in which the back surface 213 and the four side surfaces 212 intersect are formed to have a rounded shape that is chamfered. The radius of curvature of each intersection part 214 is preferably 20 μm or less, for example.

On the other hand, four intersection parts 215 which are portions in which the circuit formation surface 211 and the four side surfaces 212 intersect are formed to a have different shape from the rounded shape of the intersection part 214, and have an approximately right-angled square shape, for example. The resin film 239 overlaps the entire circuit formation surface 211 in plan view, and the periphery of the resin film 239 protrudes from the four side surfaces 212 in plan view. That is, the resin film 239 covers the four intersection parts 215. Also, the resin film 239 bulge outwardly of the semiconductor substrate 21 at the intersection parts 215. Furthermore, the resin film 239 is provided on areas of the four side surfaces 212 of the semiconductor substrate 21 that are separated from the back surface 213 toward the circuit formation surface 211.

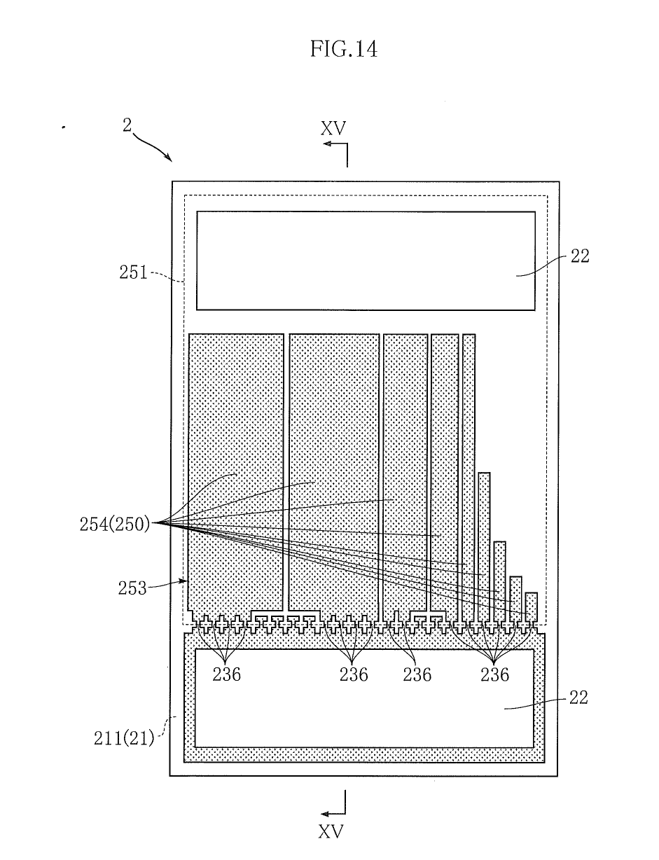

FIGS. 14 and 15 show yet another modification of the chip-type passive components 2. The chip-type passive components 2 of the present modification are constituted as chip capacitors. The chip-type passive components 2 are provided with a semiconductor substrate 21, two electrodes 22, a lower electrode film 251, a capacitive film 252 and an upper electrode film 253, and are configured to have a plurality of capacitor elements 250. The chip-type passive components 2 of the present modification may have a rectangular shape such as 0.3 mm×0.15 mm, 0.4 mm×0.2 mm (preferably 0.4 mm×0.2 mm or smaller) in plan view, for example. The region in which the plurality of capacitor elements 250 are formed is a square region whose sides are each roughly equivalent to the length of the short sides of the semiconductor substrate 21. The thickness of the semiconductor substrate 21 may be about 150 μm.

An insulating layer 217 is formed on the circuit formation surface 211 of the semiconductor substrate 21. The insulating layer 217 may be an oxide film of SiO₂ or the like. The thickness of the insulating layer 217 may be from about 500 Å to 2000 Å.

A lower electrode film 251 is formed on the insulating layer 217. The lower electrode film 251 is provided over substantially the entire area in which the plurality of capacitor elements 250 are arranged. Also, the lower electrode film 251 extends to directly under the area of one of the electrodes 22, and is in electrical contact with that electrode 22. The lower electrode film 251 is preferably a conductive film, particularly a metal film, and may be an aluminum film, for example. A lower electrode film 251 consisting of an aluminum film can be formed by sputtering.

The capacitive film 252 directly overlaps a portion of the lower electrode film 251 in which at least the plurality of capacitor elements 250 are formed. The capacitive film 252 is a dielectric film and can be constituted by a silicon nitride film, for example, the thickness of which can be from 500 Å to 2000 Å (e.g., 1000 Å). The capacitive film 252 may be a silicon nitride film formed by plasma CVD (chemical vapor deposition).

A upper electrode film 253 is formed on the capacitive film 252. In FIG. 14, the upper electrode film 253 is colored to facilitate understanding. The upper electrode film 253 is in electrical contact with the other electrode 22, and has a plurality of electrode film portions 254. Also, a plurality of fuse films 236 are provided between the portion of the upper electrode film 253 that contacts the electrode 22 and the plurality of electrode film portions 254.

The plurality of electrode film portions 254 are all rectangular in the present modification, and are arranged approximately parallel to each other. As shown in FIG. 14, the two electrode film portions 254 located on the left in the diagram have the largest area. The remaining electrode film portions 254 are arranged to decrease in area toward the right in the diagram. Each electrode film portion 254 constitutes one of the capacitor elements 250 together with the lower electrode film 251 with the capacitive film 252 interposed therebetween. The plurality of fuse films 236 are each connected in series to one of the capacitor elements 250. By setting these fuse films 236 to an open state, arbitrary capacitor elements 250 can be set as elements that are selectively not electrically connected to the two electrodes 22 and do not function as capacitors.

The upper electrode film 253 is, similarly to the lower electrode film 251, preferably constituted by a conductive film, particularly a metal film, and may be an aluminum film. An upper electrode film 253 consisting of an aluminum film can be formed by sputtering. Patterning for shaping the upper electrode film 253 to have a plurality of electrode film portion 254 and a plurality of fuse films 236 can be performed by photolithography and an etching process, for example.

A protective film 238 covers the upper electrode film 253. The protective film 238 can be constituted by a silicon nitride film, for example, and can be formed by plasma CVD, for example. The thickness of the protective film 238 may be about 8000 Å. The resin film 239 can be constituted by a resin film made of polyimide or another material, as mentioned above.

The specific configuration and functions of the semiconductor module A1 are not particularly limited, and can be variously set. To illustrate specific configurations of the semiconductor module A1, in the case where the semiconductor module A1 is employed in a mobile communication device such as a smartphone, the semiconductor module A1 functions as a transmission processing module, a one-segment TV receiving module, a GPS receiving module, FM tuner module, a power module, a main control module, or the like.

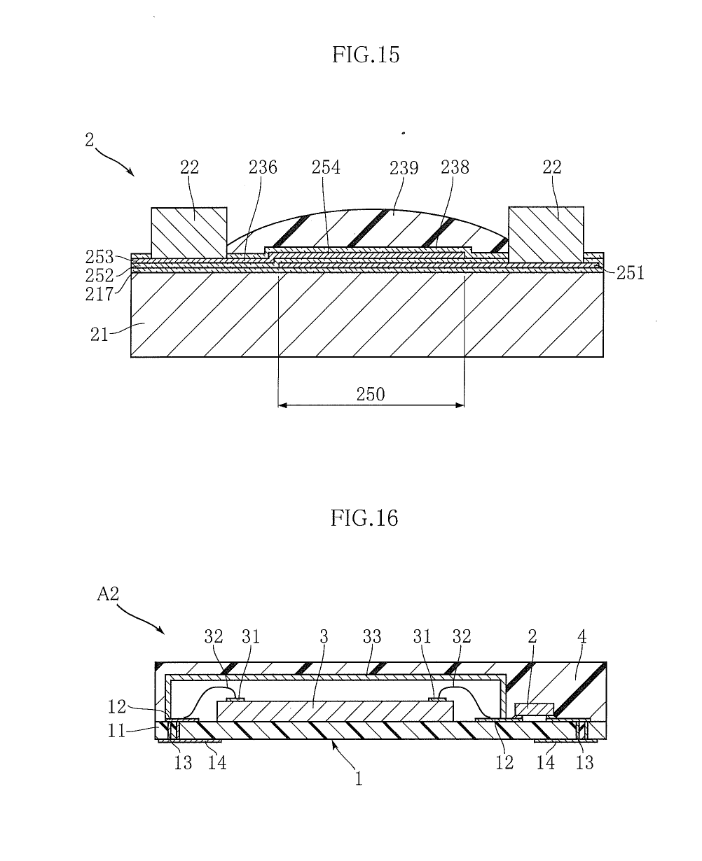

FIG. 16 shows a semiconductor module that is based on a second embodiment of the present invention. A semiconductor module A2 of the present embodiment is provided with a case 33. The case 33 is interposed between the integrated circuit device 3 and the resin sealing part 4, and has a box shape that covers the integrated circuit device 3. In the present embodiment, the case 33 covers the plurality of wires 32. The case 33 is made of a metal or a resin, for example. The inner space of the case 33 is filled with a substance that appropriately protects the integrated circuit device 3 and allows the integrated circuit device 3 to function properly. As such a substance, a resin that is the same as or different from the resin sealing part 4, an insulating paste or the like can be employed as appropriate.

According to such an embodiment, chip-type passive components 2 of remarkably small size can similarly be appropriately integrated into an electrical circuit or the like. Also, the integrated circuit device 3 can be appropriately protected from stress that is produced by the expansion and contraction of the resin sealing part 4.

FIG. 17 shows a semiconductor module that is based on a third embodiment of the present invention. A semiconductor module A3 of the present embodiment is provided with a plurality of leads 17 as conductive supporting members. The plurality of leads 17 are made of Cu, for example, and a plating film made of Ni or Au, for example, may be provided over all the leads 17 or in appropriate places.

The lead 17 arranged near the center of the diagram has an island 171. The integrated circuit device 3 is joined to the island 171. The lower surface of the island 171 in the diagram may be exposed from the resin sealing part 4.

The lead 17 arranged to the left in the diagram is bonded to one end of a wire 32. This lead 17 has a mounting electrode 172. The mounting electrode 172 is a portion in which the lower surface of a bent portion of the lead 17 in the diagram is exposed from the resin sealing part 4. The mounting electrode 172 is used in order to mount the semiconductor module A2 onto a circuit board or the like.

The chip-type passive components 2 are joined to two leads 17 arranged on the right in the diagram. A wire 32 is joined to one of these leads 17. The other lead 17 has the abovementioned mounting electrode 172.

According to such an embodiment, chip-type passive components 2 of remarkably small size can similarly be appropriately integrated into an electrical circuit or the like.

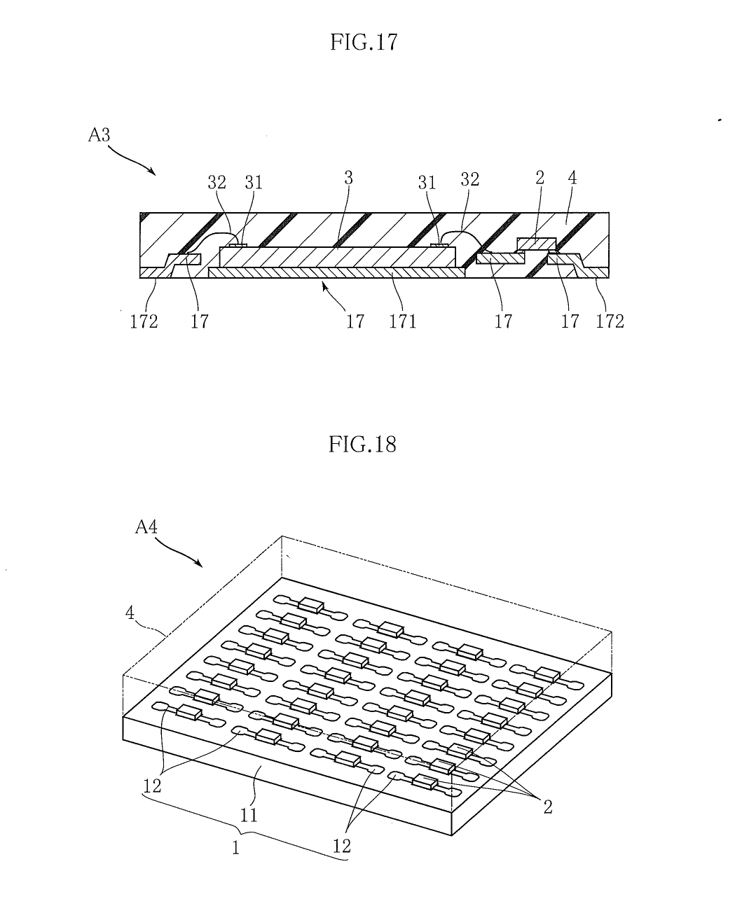

FIG. 18 shows a semiconductor module that is based on a fourth embodiment of the present invention. A semiconductor module A4 of the present embodiment differs from the abovementioned embodiments in that while a plurality of chip-type passive components 2 are provided, an integrated circuit device 3 is not provided. That is, the semiconductor module A4 is constituted as a passive module. The plurality of chip-type passive components 2 are constituted as diodes and coils in addition to the abovementioned chip resistors and chip capacitors. One or more types of these chip-type passive components 2 are mounted together onto the wiring board 1. The wiring patterns 12 have, in addition to the portion provided on the surface of the base material 11, conduction paths that are in electrical contact with each other as appropriate in intermediate layers that are located within the base material 11, for example.

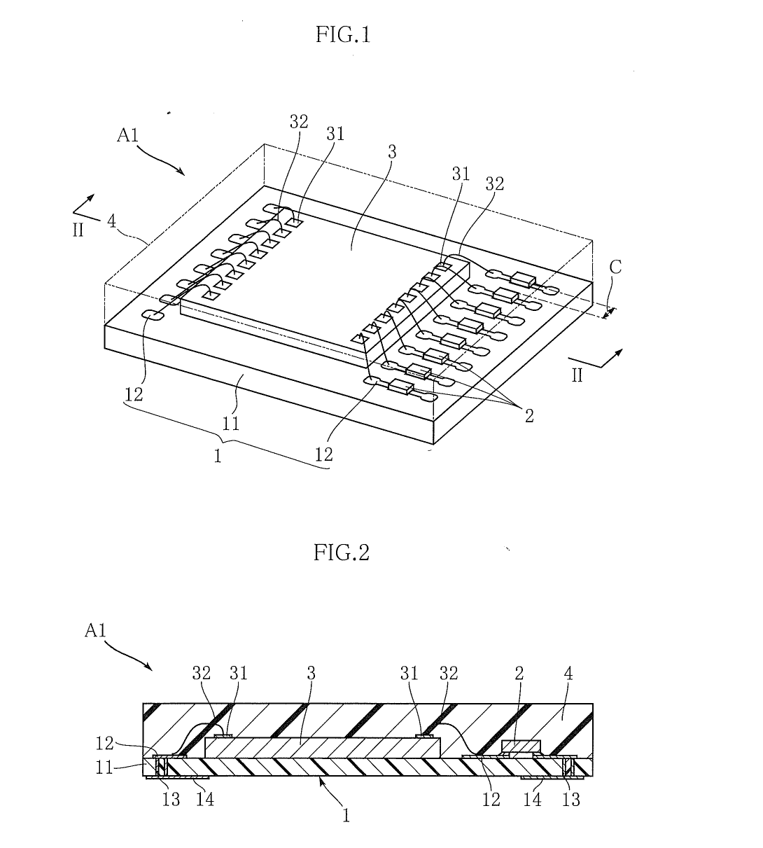

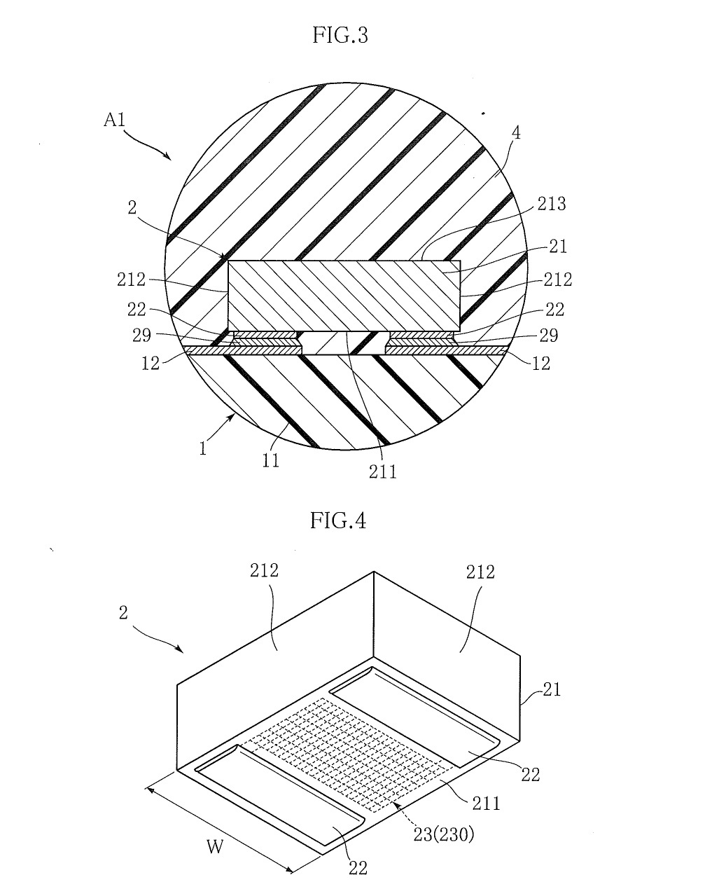

For example, in the case where the plurality of chip-type passive components 2 only consist of chip resistors, a configuration can be realized in which the resistance of the semiconductor module A4 is remarkably high, by connecting these chip-type passive components 2 in series. Alternatively, a configuration can also be adopted in which three or more of the mounting electrodes shown in FIG. 2 are provided. In this case, a plurality of types of resistances can be set using one semiconductor module A4, by differentiating the number, specification and the like of chip-type passive components 2 arranged between any two mounting electrodes 14.

Also, in the case where the plurality of chip-type passive components 2 only consist of chip capacitors, a configuration can be adopted in which the plurality of chip-type passive components 2 are connected in parallel to each other. The semiconductor module A4 is thereby able to realize a remarkably low resistance together with achieving increased capacity. According to such an embodiment, chip-type passive components 2 of remarkably small size can similarly be appropriately integrated into an electrical circuit or the like.

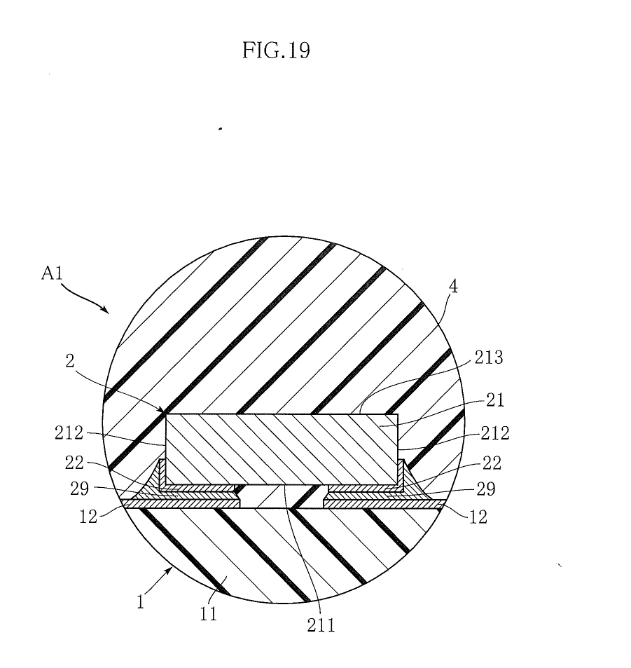

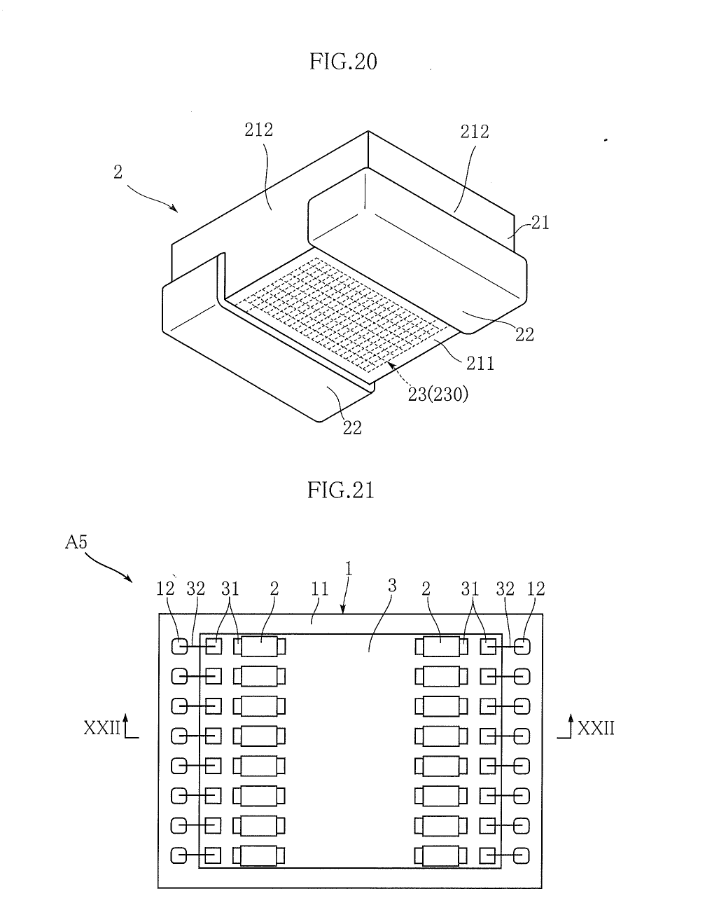

FIGS. 19 and 20 show a modification of the semiconductor module A1. In the present modification, the configuration of the chip-type passive components 2 differs from the abovementioned configuration. Note that the present modification is not limited to only the semiconductor module A1, and can also be employed in the semiconductor modules A2 to A4 as appropriate.

In the present modification, the electrodes 22 of the chip-type passive components 2 cover not only the circuit formation surface 211 of the semiconductor substrate 21 but also a portion of side surfaces 212. More specifically, as shown in FIG. 20, each electrode 22 covers a portion of one circuit formation surface 211 and a portion of three side surfaces 212. As shown in FIG. 19, in the case where the chip-type passive components 2 of the present modification are mounted using the solder 29, the solder 29 also adheres to the portion of the electrodes 22 that covers the side surfaces 212. As a result, the region called a solder fillet is formed in the solder 29. The solder 29 having such a solder fillet is convenient for judging, visually or through image processing, the suitability of mounted chip-type passive components 2.

FIGS. 21 to 23 show a semiconductor module that is based on a fifth embodiment of the present invention. The semiconductor module A5 of the present embodiment differs from the abovementioned embodiments in the form in which the chip-type passive components 2 are mounted. FIG. 21 is a plan view showing a main portion of the semiconductor module A5, with the resin sealing part 4 having been omitted to facilitate understanding.

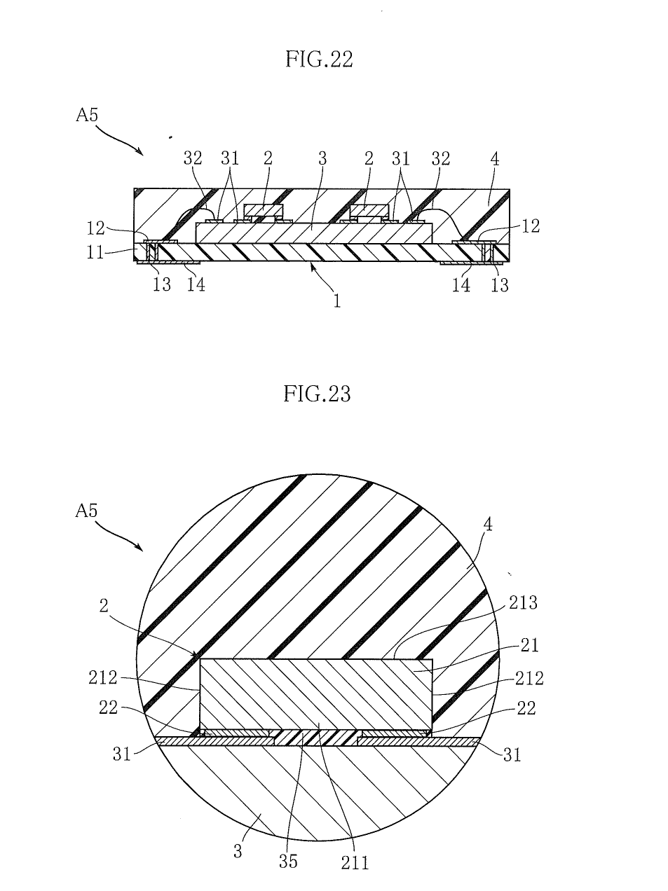

In the present embodiment, a plurality of chip-type passive components 2 are mounted directly onto the integrated circuit device 3. A plurality of pads 31 are formed on the integrated circuit device 3. As shown in FIG. 23, the plurality of chip-type passive components 2 are mounted onto the integrated circuit device 3 by eutectically bonding the electrodes 22 and the pads 31. Preferable combinations for eutectic bonding include eutectic bonding of Au and Au and eutectic bonding of Au and Sn. As shown in FIGS. 21 and 22, the wires 32 are bonded to some of the pads 31. The plurality of chip-type passive components 2 are mounted onto the plurality of pads 31 arranged on the inner side of the pads 31 to which the wires 32 are bonded. Also, in the present embodiment, the chip-type passive components 2 are not mounted onto the wiring board 1. Thus, the semiconductor module A5 is able to reduce the dimensions in plan view, compared to a configuration in which a plurality of chip-type passive components 2 are mounted onto the wiring board 1.

As shown in FIG. 23, the region between the circuit formation surface 211 of the semiconductor substrate 21 of the chip-type passive components 2 and the integrated circuit device 3 is filled with an underfill resin 35. The underfill resin 35 is formed by curing a liquid resin material having comparatively high fluidity. In the manufacture of the semiconductor module A5, the liquid resin material is poured into the region between the circuit formation surface 211 and the integrated circuit device 3 prior to forming the resin sealing part 4, after mounting the chip-type passive components 2 onto the integrated circuit device 3. The underfill resin 35 is obtained when this liquid resin material cures. The underfill resin 35 helps to avoid an unintended gap occurring between the circuit formation surface 211 and the integrated circuit device 3.

The semiconductor module according to the present invention is not limited to the abovementioned embodiments. Various design changes can be freely implemented with respect to the specific configuration of each part of the semiconductor module according to the present invention.

The chip-type passive components 2 are not particularly limited as long as the passive circuit 23 formed on the semiconductor substrate 21 is provided, and may be chip diodes, for example, in addition to the abovementioned chip resistors and chip capacitors.

1. A semiconductor module comprising:
a plurality of chip-type passive components each including a semiconductor substrate, a plurality of electrodes formed on the semiconductor substrate, and a passive circuit formed on the semiconductor substrate and connected between the plurality of electrodes;
a conductive supporting member onto which the plurality of chip-type passive components are mounted; and
a resin sealing part covering the plurality of chip-type passive components and at least a portion of the conductive supporting member.

2. The semiconductor module according to claim 1, wherein the semiconductor substrate of the chip-type passive components directly contacts the resin sealing part.

3. The semiconductor module according to claim wherein the passive circuit includes a resistive network.

4. The semiconductor module according to claim 3, wherein the resistive network includes: a plurality of resistive elements arrayed on the substrate in a matrix and having equal resistance; a plurality of types of resistor unit bodies configured by electrically connecting to one or more of the resistive elements; a network connection means connecting the plurality of types of resistor unit bodies; and a plurality of fuse films provided in one-to-one correspondence with the resistor unit bodies, and blowable in order to electrically integrate the respective resistor unit bodies into the resistive network or to electrically isolate the respective resistor unit bodies from the resistive network.

5. The semiconductor module according to claim 4, wherein the resistive elements include a resistor film line that extends on the substrate, and a conductor film laminated on the resistor film line with a fixed interval provided in a line direction, and a portion of the resistor film line that is located in the fixed interval portion where the conductor film is not laminated constitutes one resistive element.

6. The semiconductor module according to claim 4, wherein a conductor film of the resistive elements, a connecting conductor film included in the resistor unit bodies, a connecting conductor film included in the network connection means, and the fuse films include a metal film of the same material formed in the same layer.

7. The semiconductor module according to claim 3, wherein, in a circuit formation surface of the substrate, a trench dug to a predetermined depth from the circuit formation surface is formed, and
the resistive network includes a resistor circuit having a resistive film provided along an inner wall surface of the trench so as to traverse the trench.

8. The semiconductor module according to claim 7, wherein the resistive network includes:
a plurality of resistor circuits, and
a fuse film blowable in order to electrically integrate an arbitrary resistor circuit into the resistive network or to electrically isolate an arbitrary resistor circuit from the resistive network.

9. The semiconductor module according to claim 8, wherein the resistive film has a fixed width, and includes a line-like resistor film line that extends linearly.

10. The semiconductor module according to claim 8, wherein the resistive film is formed to extend from an inner surface of the trench to the circuit formation surface outside the trench, and
the semiconductor module further comprises a wiring film formed in contact with a portion of the resistive film that is formed on the circuit formation surface.

11. The semiconductor module according to claim 7, wherein the trench extends in a predetermined direction, when the circuit formation surface is seen in plan view, and
the resistive film includes a plurality of parallelly arrayed resistor film lines provided along the inner wall surface of the trench so as to traverse the trench, and extending orthogonally to the direction in which the trench extends.

12. The semiconductor module according to claim 1, wherein the passive circuit includes a plurality of capacitor elements.

13. The semiconductor module according to claim 12, wherein the passive circuit includes a plurality of fuse films blowable in order to electrically integrate the plurality of capacitor elements between the plurality of electrodes or to electrically isolate the plurality of capacitor elements from between the plurality of electrodes.

14. The semiconductor module according to claim 13, wherein the passive circuit includes a lower electrode film, a capacitive film, and an upper electrode film that are laminated on the substrate, and
one of the lower electrode film and the upper electrode film is divided into a plurality of electrode film portions.

15. The semiconductor module according to claim 1, wherein the substrate has a circuit formation surface, a back surface on an opposite side to the circuit formation surface, and a side surface connecting the circuit formation surface and the back surface,
the passive circuit and the plurality of electrodes are formed on the circuit formation surface,
the semiconductor module further comprises a resin film covering the circuit formation surface in a state where the plurality of electrodes are exposed, and
an intersection part where the back surface and the side surface of the substrate intersect has a rounded shape.

16. The semiconductor module according to claim 15, wherein a radius of curvature of the rounded shape is 20 μm or less.

17. The semiconductor module according to claim 15,
wherein an intersection part where the circuit formation surface and the side surface of the substrate intersect has a different shape from the rounded shape.

18. The semiconductor module according to claim 17, wherein the resin film covers the intersection part where the circuit formation surface and the side surface of the substrate intersect.

19. The semiconductor module according to claim 18, wherein the resin film bulges outwardly of the substrate at the intersection part where the circuit formation surface and the side surface of the substrate intersect.

20. The semiconductor module according to claim 19, wherein the resin film is provided on areas of the side surface of the substrate that are separated from the back surface toward the circuit formation surface side.

21. The semiconductor module according to claim 1, further comprising an integrated circuit device mounted onto the conductive supporting member and in electrical contact with the plurality of passive components.

22. The semiconductor module according to claim 21, wherein the integrated circuit device is in electrical contact with the conductive supporting member via a plurality of wires.

23. The semiconductor module according to claim 21, wherein the integrated circuit device directly contacts the resin sealing part.

24. The semiconductor module according to claim 21, further comprising a case interposed between the integrated circuit device and the resin sealing part.

25. The semiconductor module according to claim 21, wherein the integrated circuit device is mounted directly onto the conductive supporting member.

26. The semiconductor module according to claim 25, wherein the plurality of passive components include passive components mounted directly onto the integrated circuit device.

27. The semiconductor module according to claim 1, wherein the conductive supporting member is a wiring board including a base material made of an insulating material and a wiring pattern formed on the base material.

28. The semiconductor module according to claim 1, wherein the conductive supporting member includes a plurality of leads each made of a metal.

29. The semiconductor module according to claim 1, wherein the chip-type passive components are mounted directly onto the conductive supporting member.

30. The semiconductor module according to claim 1, wherein the plurality of passive components include passive components arranged adjacent to each other having dimensions in an adjacent direction of 0.05 to 0.3 mm and a gap therebetween of 50 to 150 μm.
